(19) United States
(12) Patent Application Publication
(10) Pub. No.: US 2023/0063115 A1
(43) Pub. Date: Mar. 2, 2023

(54) PVD COATED CEMENTED CARBIDE CUTTING TOOL WITH IMPROVED COATING ADHESION

(71) Applicant: WALTER AG, Tubingen (DE)

(72) Inventor: Veit SCHIER, Tubingen (DE)

(21) Appl. No.: 17/793,990

(22) PCT Filed: Jan. 21, 2021
(86) PCT No.: PCT/EP2021/051331

§ 371 Date: Jul. 20, 2022

(30) Foreign Application Priority Data
Jan. 21, 2020 (EP) 20152868.4

(51) Int. Cl. C23C 14/34; C23C 14/06

(52) U.S. Cl. CPC C23C 14/3485; C23C 14/0635; C23C 14/345

(57) ABSTRACT

A coated cutting tool includes a substrate of cemented carbide, cubic boron nitride (cBN) or cermet containing tungsten carbide hard grains and a tungsten carbide (WC) layer deposited immediately on top of the substrate surface. The tungsten carbide (WC) layer is a mixture or combination of hexagonal tungsten mono-carbide α-WC phase and cubic tungsten mono-carbide β-WC phase and unavoidable impurities.

### FIELD OF THE INVENTION

The present invention relates to a coated cutting tool, preferably a coated cutting tool for metal machining and metal cutting operations, comprising or consisting of a substrate of cemented carbide, cermet containing tungsten carbide hard grains or cubic boron nitride (cBN), and a tungsten carbide (WC) layer deposited immediately on top of the substrate surface.

The invention further relates to a process for the manufacturing of such a tool.

### BACKGROUND OF THE INVENTION

Cutting tools, such as those used for metal cutting, generally consist of a substrate made of cemented carbide (also referred to as hard metal), cermet, cubic boron nitride (cBN), steel or high-speed steel having a single-layer or multi-layer coating of wear resistant hard material deposited thereon by means of CVD or PVD.

Cemented carbide substrates consist of WC hard phase grains of hexagonal crystal structure, optionally further hard materials of cubic crystal structure, such as TiC, TaC, NbC etc., and a binder phase of Co, Fe and/or Ni, mostly of Co. Cemented carbides are produced by powder metallurgical methods, wherein the starting powders are mixed, milled, formed into a green body, pre-sintered and sintered.

A hard wear resistant coating may then be deposited by PVD or CVD immediately onto the cemented carbide substrate outer surface. In most cases, the first layer deposited immediately on the substrate surface (also referred to as base layer or adhesion layer) is a cubic single-metal or mixed-metal carbide, nitride or carbonitride layer, such as TiC, TiN, TiCN, TiAlN or TiAlCN, since these layers are known to improve adhesion between the cemented carbide substrate surface and subsequent hard coating layers. The hard wear resistant coating layers of the coating generally include single-metal or mixed-metal carbides, nitrides, oxides, carbonitrides, oxycarbides, oxynitrides etc. of the group 4, 5 and 6 transition metals of the periodic table, Al or Si. In this technological field and in the context of the present invention these layer materials are referred to as “hard materials”.

In the cemented carbide substrate the hard WC grains are embedded in a network of the binder phase, such as Co, which interpenetrates the entire substrate body. At the outer surface of the substrate the binder phase is exposed as binder veins (in the following referred to as Co veins) between the exposed surfaces of the embedded WC grains. A disadvantage of the exposure of such Co veins at the outer surface is that the binder metal is chemically not very stable, and during deposition of the hard coating chemical diffusion of the binder metal into the coating material may occur with the consequence of chemically and mechanically weakening the coating layer material. From a mechanical point of view, hardness and Young's modulus may thereby be impaired.

Also, since the crystal systems at the interface between the surfaces of the hexagonal WC grains exposed at the substrate surface and the usually cubic first layer hard material deposited thereon, such as TiN or TiAlN, are different, the mechanical strength of the bond between the substrate surface and the coating is limited, especially under thermal and mechanical load.

### OBJECT OF THE INVENTION

It is therefore an object of the present invention to overcome the afore-mentioned disadvantages of prior art cutting tools.

It is another object of the present invention to provide a coated cutting tool with improved wear resistance and service life, and wherein the hard material coating exhibits high hardness, a high Young's modulus (modulus of elasticity) and, at the same time, good adherence of the coating to the substrate.

It is yet another object of the present invention to provide a method for manufacturing such a coated cutting tool with improved properties.

### DESCRIPTION OF THE INVENTION

The present invention is directed to a coated cutting tool comprising or consisting of a substrate of cemented carbide, cermet containing tungsten carbide hard grains or cubic boron nitride (cBN), and a tungsten carbide (WC) layer deposited immediately on top of the substrate surface, wherein the tungsten carbide layer consists of a mixture or combination of hexagonal tungsten mono-carbide α-WC phase and cubic tungsten mono-carbide β-WC phase and unavoidable impurities.

In a preferred embodiment of the present invention the substrate consists of cemented carbide at least containing WC (tungsten carbide) hard material grains and from about 3% to 30%, preferably from 5% to 15% of binder phase of Co, Fe and/or Ni, preferably of Co. In another preferred embodiment the substrate further contains hard materials of cubic crystal structure, such as TiC, TaC, NbC or solid solutions thereof, as they are well known and generally applied in cemented carbide tool substrates.

The tungsten carbide layer of the coated cutting tool of the present invention has a thickness of from 1 nm to 5 μm. Knowing the present invention, the skilled person will be able to easily determine and optimize the layer thickness depending on the requirements of the cutting tool, i.e. intended cutting operation and workpiece material, and whether or not and which type of further hard coating layers are provided on top of the inventive tungsten carbide layer.

In a preferred embodiment of the invention the thickness of the tungsten carbide layer is within the range from 10 nm to 1 μm or from 20 nm to 100 nm. If the tungsten carbide layer is too thin, the effect thereof may be too low. If the tungsten carbide layer is too thick, depending on the type and thickness of additional hard coating layers deposited on top of the tungsten carbide layer, the overall layer thickness may become too high, and a too high overall coating thickness may impair adhesion of the coating and lead to early wear, flaking and peeling off of the hard coating.

Depending on the intended cutting operation and work piece material, prior art tools for metal cutting, especially those having a cemented carbide body, are used either uncoated or are provided with a single-layer or multi-layer refractory hard material coating deposited on top of the surface of the body by CVD or PVD techniques.

Even though uncoated cemented carbide cutting tools may be preferred in certain metal cutting operations from a mechanical point of view, a disadvantage arising especially at higher cutting operation temperatures may be diffusion of binder phase out of the cutting tool body. Thereby a film or smear of binder material is generated between the cutting tool and the workpiece, which in turn leads to increased friction, impaired chip-forming and other disadvantages. Further, especially in machining of iron and low alloyed steels at high temperature, iron may diffuse into the cemented carbide body and deteriorate the mechanical properties of the cutting edge.

These disadvantages are overcome by an embodiment of the present invention, wherein the tungsten carbide (WC) layer deposited immediately on top of the substrate surface is the only and outermost coating layer of the cutting tool of the present invention. For definition purposes, optionally, this embodiment includes those tools having an additional decorative layer on top of the tungsten carbide (WC) layer, such as a thin TiN or ZrN layer, which is often applied essentially for decorative purposes and/or as an indicator of tool use and wear, but which does not significantly change the tool's mechanical properties.

An advantage of this embodiment compared to uncoated cemented carbide, cBN or cermet tools is that the tungsten carbide (WC) layer deposited immediately on top of the substrate surface provides a barrier against diffusion of binder phase out of the tool body during the cutting operation, especially at high temperature. The mechanical properties of such an inventive cutting tool are comparable to or even improved over those having an uncoated cutting body, and at the same time binder diffusion out of the body and/or iron diffusion into the body are prohibited. Advantages of this embodiment of the present invention are less deterioration of the mechanical properties of the tool body, improved wear resistance and tool life, less adhesion and friction between tool and work piece due to avoidance of binder smear. Further, depending on its thickness, the inventive tungsten carbide (WC) layer provides increased hardness and/or Young's modulus (modulus of elasticity) to the cutting edge of the tool.

### Tungsten Carbide Phases

Group 4, 5 and 6 transition metal carbides offer the highest melting points and hardness values among known compounds. Owing to this, they are widely used in the production of structural and tool materials capable of working at high temperatures, in aggressive environments, and under high loads. Compared to other transition metal carbides the hardness of WC is very stable and decreases relatively little compared to other carbides as the temperature is raised from room temperature to about 900-1100° C. In addition, WC has a factor of 1.5-2 higher elastic modulus and a factor of 1.5-2 smaller thermal expansion coefficient in comparison with other transition metal carbides. It is this combination of properties and their thermal stability which underlie the wide use of WC in the production of wear-resistant hard alloys.

The compounds existing in the binary W—C system are the tungsten mono-carbide WC (W₁C₁) and the tungsten semi-carbide (W₂C). Both compounds have several polymorphic modifications.

There are two polymorphic forms of the tungsten mono-carbide WC, a hexagonal form, α-WC, also referred to as h-WC (h=“hexagonal”), and a cubic form, β-WC, also referred to as c-WC (c=“cubic”), which has the rock salt structure. The hexagonal form, α-WC, can be visualized as made up of a simple hexagonal lattice of metal atoms of layers lying directly over one another (i.e. not close packed), with carbon atoms filling half the interstices giving both tungsten and carbon a regular trigonal prismatic, 6 coordination. The cubic β-WC is described as a metastable or even as an unstable high-temperature form. In the literature, β-WC is often denoted as β-WC₁₋ₓ. However, it is assumed that both, the hexagonal α-WC and the cubic β-WC, have a 1:1 stoichiometry, i.e., x is zero or near zero in the sometimes so-called β-WC₁₋ₓ.

From the semi-carbide W₂C four polymorphs (α, β, γ and ε) are known. α-W₂C, β-W₂C and γ-W₂C have the hexagonal crystal structure, wherein the W atoms form an hexagonal closed packed (hcp) sublattice, in which half of the octahedral interstices are occupied by carbon atoms. Depending on the arrangement of carbon atoms, W₂C may be disordered (at high temperatures) or ordered (at low temperatures).

Based on formation energy (E_{form}) calculations, the stabilities of the several tungsten mono-carbide WC and semi-carbide W₂C phases (polymorphs) are described in the literature in the following sequence: α-WC>ε-W₂C>β-W₂C>γ-W₂C>α-W₂C>β-WC. Under this criterion, three carbides (α-WC, ε-W₂C and β-W₂C) are stable (E_{form}<0), γ-W₂C belongs to metastable systems (E_{form}˜0), whereas the hexagonal α-W₂C and the cubic β-WC are described as being unstable (E_{form}>0); (Dmitrii V. Suetin, Igor R. Shein, Alexander L. Ivanovskii, “Structural, electronic properties and stability of tungsten mono- and semi-carbides: A first principles investigation”, Journal of Physics and Chemistry of Solids, Vol 70, Issue 1, January 2009, pages 64-71). Considering these results described in the literature on stability of tungsten carbides, especially of the cubic tungsten monocarbide β-WC described as being unstable, it was surprising to the inventors that a stable combination of hexagonal tungsten mono-carbide α-WC and cubic tungsten mono-carbide β-WC could be formed in a tungsten carbide layer with improved mechanical properties, high hardness and high Young's modulus.

For the purpose of the present invention, the crystal structures and polymorphic modifications of the tungsten carbides in the tungsten carbide layer are investigated and determined by X-ray diffraction (XRD; Cu Kα radiation), and the diffraction peaks are indexed using the following JCPDS cards:
α-WC JCPDS 025-1047
β-WC JCPDS 020-1316
α-W₂C JCPDS 035-0776

The hexagonal α-W₂C semi-carbide phase provides brittleness to the coating layer resulting in bad mechanical properties of the coating. Therefore, the hexagonal α-W₂C semi-carbide phase is considered detrimental and thus undesired in the present invention. The tungsten carbide (WC) layer is free from measurable amounts of hexagonal α-W₂C semi-carbide phase, when measured by XRD. Accordingly, the inventive tungsten carbide (WC) layer of the present invention is free from measurable amounts of hexagonal α-W₂C semi-carbide phase, as far as measurable by the XRD method described herein below. Measurable amounts of hexagonal α-W₂C are also excluded from the meaning of the term “unavoidable impurities”, as it is used herein and in the claims.

In an alternative preferred embodiment of the present invention a single-layer or multi-layer hard material coating is deposited immediately on top of the tungsten carbide layer, wherein the hard material coating includes at least one layer, preferably two or more layers of hard material selected from the group consisting of nitrides, carbides, oxides, borides and/or solid solutions thereof of one or more of the elements selected from Ti, Zr, Hf, V, Nb, Ta, Cr, Mo, W, Al and Si. Preferred hard materials are TiN, TiC, TiAlN, TiAlC, TiAlCN, α-Al₂O₃ and γ-Al₂O₃.

The hard coating on top of the tungsten carbide layer of the present invention provides further improved mechanical and tribochemical properties to the cutting tool, such as improved wear resistance and tool life, less adhesion and friction between tool and work piece, improved hardness and/or toughness and/or Young's modulus (modulus of elasticity) to the cutting edge of the tool.

In another preferred embodiment of the coated cutting tool of the present invention, the amount of hexagonal tungsten mono-carbide α-WC phase within the tungsten carbide (WC) layer decreases and the amount of cubic tungsten mono-carbide β-WC phase increases from the interface at the surface of the substrate towards the outer surface of the tungsten carbide (WC) layer. The increase can be gradually or stepwise, preferably gradually.

As stated above, the crystal structures and polymorphic modifications (phases) of the tungsten carbides in the tungsten carbide layer are investigated and determined by X-ray diffraction (XRD). Even though this method does not allow for a determination of absolute amounts of each of the phases, XRD can be used to confirm presence or absence of a certain WC phase. Furthermore, XRD allows for evaluation of differences of the relative amounts of hexagonal tungsten mono-carbide α-WC phase compared to cubic tungsten mono-carbide β-WC phase within separate tungsten carbide layers deposited under different deposition parameters. Different relative amounts of the phases result in different relations (ratios) of the XRD peak intensities of the phases. However, since XRD measures throughout the entire layer thickness it does not allow for the determination of different relative amounts of hexagonal tungsten mono-carbide α-WC phase compared to cubic tungsten mono-carbide β-WC phase within one and the same tungsten carbide layer. Therefore, in the sense of the present invention, changes of relative amounts of different WC phases throughout the thickness of one and the same tungsten carbide layer may be determined by TEM (transmission electron microscopy) on a cross-section polish of the coating.

The change from higher to lower amounts of hexagonal tungsten mono-carbide α-WC phase and from lower to higher amounts of cubic tungsten mono-carbide β-WC phase from the interface at the surface of the substrate towards the outer surface of the tungsten carbide (WC) layer has several advantages. A higher amount of hexagonal tungsten mono-carbide α-WC phase at the interface with the surface of the substrate provides improved adhesion to the substrate due to two adhesion improving factors, same chemical composition as and structural coherence with the hexagonal WC grains of the substrate, which are exposed at the substrate surface and onto which inventive tungsten carbide layer is deposited. This can, for example, be seen in the attached FIGS. 1 and 2. The coherent growth of the inventive tungsten carbide layer onto the hexagonal WC grains of the substrate appears as columns or small teeth would protrude from the surface of the WC grains of the substrate into the tungsten carbide layer. However, the original substrate surface, as it was prior to the deposition of the tungsten carbide layer, was very smooth and flat and is marked in the figures by a black line. The protrusions extending from the WC grains beyond the black line are part of and belong to the deposited tungsten carbide layer, but they appear as they would belong to the WC grains of the substrate. This appearance of the growth of the tungsten carbide layer on the WC grains of substrate surface is herein referred to as coherent growth.

In contrast to that, conventional hard material multi-layer coatings on cemented carbide cutting tool substrates start with a base layer, often referred to as adhesion layer, of different chemical composition and different structure. Well established base or adhesion layers on cemented carbide tool substrates are Ti(C,N) or TiAl(C,N) layers, i.e., layers of different chemistry and different crystal structure (fcc). Such cubic base or adhesion layers are known to provide good adhesion to the cemented carbide substrate and an even better adhesion to subsequent hard material layers, since such subsequent layers usually have the same or similar chemistry and often also the same cubic crystal structure. However, the inventive tungsten carbide layer is suitable to still improve adhesion and to form a barrier against diffusion of binder from the Co veins of the substrate into the coating.

A higher amount of cubic tungsten mono-carbide β-WC phase towards the outer surface of the tungsten carbide (WC) layer is suitable to further improve adhesion of a subsequent also cubic hard material layer due to the approach to a more similar crystal structure.

Further, the inventive tungsten carbide layer allows for adjusting the mechanical properties of the layer by adjusting the fraction or amount of cubic tungsten mono-carbide β-WC phase relative to hexagonal tungsten mono-carbide α-WC phase within the layer, either by producing a constant relation between these two phases throughout the entire layer thickness, or by increasing the amount of cubic tungsten mono-carbide β-WC phase relative to hexagonal tungsten mono-carbide α-WC phase from the substrate surface towards the tungsten carbide layer surface.

The adjustment of the relative amounts of cubic tungsten mono-carbide β-WC phase and hexagonal tungsten mono-carbide α-WC phase can be used to optimize hardness and Young's modulus (modulus of elasticity) of the tungsten carbide layer according to the demands and requirements of the cutting tool. The adjustment can be done by varying the deposition parameters and reactive gas flows, as described herein below.

Accordingly, in an embodiment of the present invention the tungsten carbide (WC) layer has a Vickers hardness HV0.015≥2500, preferably ≥2600, more preferably ≥2700, and/or a reduced Young's modulus>450 GPa, preferably >470 GPa, more preferably >490 GPa.

The tungsten carbide (WC) layer of the coated cutting tool of the present invention is deposited by a PVD method selected from HIPIMS (high power impulse magnetron sputtering) and DMS (dual magnetron sputtering). Preferably the tungsten carbide (WC) layer is deposited by HIPIMS.

In HIPIMS the magnetron is operated in the pulsed mode at high current densities resulting in an improved layer structure in the form of particularly dense layers due to high ionization of the sputtered material. In the HIPIMS method the current densities at the target typically exceed that of the conventional DMS. In the HIPIMS process micro-crystalline or nano-crystalline layer structures are obtained, which exhibit an improved wear behavior and longer service lives associated therewith. HIPIMS layers are usually somewhat harder than the DMS layers, but they also show disadvantages with respect to their adhesion to many substrates.

However, the present invention has turned out to provide improved adhesion of the inventive tungsten carbide (WC) layers deposited in the HIPIMS process. And, in embodiments of the present invention with further hard material coatings, the inventive tungsten carbide (WC) layer is suitable to also improve the adhesion of such additional layers.

Another advantage of the inventive tungsten carbide (WC) layer over conventional cubic hard material layers deposited immediately on top of the substrate surface is its much lower thermal conductivity. For example, the hexagonal tungsten mono-carbide α-WC phase has a thermal conductivity of ˜8 W/Km, whereas typical cubic metal nitrides conventionally used as adhesion layers on the substrate, such as TiN, have thermal conductivities in the range from about 20-30 W/Km. The lower thermal conductivity of the inventive tungsten carbide (WC) layer is suitable to protect the substrate material from heat damage, especially in cutting operations where high temperatures occur, such as high speed metal machining.

The coated cutting tool of the present invention has improved wear resistance and a good service life compared to the prior art, and the coating exhibits high hardness, a high Young's modulus (modulus of elasticity) and, at the same time, is suitable to provide good toughness and improved adherence of the coating to the substrate. These properties are advantageous in respect of wear resistance, crack resistance, flaking resistance and tool life.

The present invention further includes the use of the coated cutting tool of the present invention for metal cutting, and it is particularly suitable for the machining of steel of the groups of work piece materials characterized as ISO-P and ISO-M, according to DIN ISO standard 513.

ISO-P and ISO-M steels put high demands on fatigue resistance of the tool, and the coated cutting tools of the present invention have shown to exhibit high fatigue resistance and, at the same time, high hardness, a high Young's modulus, good toughness and good adherence.

The present invention further includes a process for manufacturing the coated cutting tool of the present invention, wherein the tungsten carbide (WC) layer immediately on top of the substrate is deposited by HIPIMS or DMS using a target of WC or WC₁₋ₓ or WC₁₊ₓ (x being from >0 to 1) and a reaction gas composition comprising or consisting of argon (Ar) and a carbon source gas, preferably C₂H₂, wherein the carbon source gas is provided at a partial pressure within the range from at least 4×10⁻⁵ mbar to at most 2.0×10⁻⁴ mbar, preferably from 8×10⁻⁵ mbar to 1.6×10⁻⁴ mbar, more preferably from 1.0×10⁻⁴ mbar to 1.6×10⁻⁴ mbar, most preferably at least 1.3×10⁻⁴ mbar, and wherein the bias voltage is within the range from 80 to 250 V, preferably from 100 to 220 V, most preferably at least 150 V.

Alternatively, the carbon source gas, preferably C₂H₂, is provided at a partial pressure within the range from 8×10⁻⁵ mbar to 1.3×10⁻⁴ mbar.

The inventors have found that the partial pressure of the carbon source should set within a suitable range (process window) to obtain a WC layer deposition with an about 1:1 stoichiometric ratio of W:C and to avoid the formation of undesired semi-carbide W₂C. Even if a WC target with a 1:1 stoichiometric ratio of W and C is used in the deposition process, it is assumed that due to the much lower weight of carbon compared to tungsten a depletion of carbon will occur during the process resulting in an under-stoichiometric layer composition. On the other hand, a too high amount of carbon source will result in the deposition of additional C phases (graphite or amorphous C, respectively). Both, too high and too low amounts of carbon source result in bad mechanical properties. Thus, a suitable process window of carbon source partial pressure has to be applied in the deposition process to obtain the inventive tungsten carbide layer with beneficial mechanical properties, such as high hardness and high Young's modulus.

The preferred carbon source in the process of the present invention is C₂H₂. As an alternative, methane, CH₄, may also be used as the carbon source in the process of the present invention. However, C₂H₂ is preferred as the reactive process gas carbon source because it generates much less of undesired hydrogen than CH₄ in the reactive deposition process.

Preferably, the target used in the inventive PVD deposition process is a WC target of an about 1:1 stoichiometric ratio of W and C. As an alternative, a pure W metal target or a target with a stoichiometric excess of C (WC₁₊ₓ) or a stoichiometric deficit of C (WC₁₋ₓ) may also be used. However, in this case excess or deficit of carbon will then have to be balanced accordingly by adjustment of the carbon source partial pressure (flow) in the reaction gas composition to avoid under-stoichiometric or over-stoichiometric deposition of the tungsten carbide layer.

It has been found that the bias voltage in the process of the present invention should be within the range from 80 to 250 V. A comparably high bias voltage within this range is beneficial to obtain a combination of hexagonal tungsten mono-carbide α-WC and cubic tungsten mono-carbide β-WC without detectable amounts of detrimental and thus undesired hexagonal semi-carbide α-W₂C.

It has further been observed that a higher bias voltage resulted in an improvement of the coherent transition from the WC grain surfaces exposed on the substrate surface into the tungsten carbide (WC) coating layer. If the bias voltage is too low, no or much less coherent growth of the tungsten carbide layer on the surfaces of the WC grains is observed.

It has turned out particularly advantageous to obtain the desired mechanical properties and, at the same time, coherent growth on the substrate surface, if the tungsten carbide layer is deposited by HIPIMS at a partial pressure of carbon source gas C₂H₂ of about 1.3×10⁻⁴ mbar and a bias voltage of 150 V to 200 V.

The term “coherent”, as it is used in the context of the present invention, means that the crystalline growth orientation of the deposited tungsten carbide (WC) layer on the surfaces of the WC grains is the same as or similar to the crystalline orientation exposed on the WC grain surfaces. To be more precise, in the sense of the present invention the term “coherent” also includes “partly coherent”, which means that the growth of the deposited tungsten carbide layer on the surfaces of the WC grains does not need to be fully coherent, but exhibits a significant amount of coherent growth orientation, which results in the observed improved adherence of the layer to the substrate surface and the very smooth transition in the SEM cross-section.

Not being bound by theory, the inventors assume that a comparably high bias voltage in the deposition process promotes coherent growth already during nucleation of the tungsten carbide layer deposition on the exposed WC grain surfaces of the substrate. The inventors believe that both coherent and non-coherent nucleation take place on the WC grain surface. However, nucleation of coherent nuclei predominates due to the template effect of the structure and crystal orientation of the exposed WC grain surfaces, and, since the bonding of coherent nuclei is stronger than that of non-coherent nuclei due to this structural similarity, the comparably high bias promotes removal of non-coherent nuclei rather than coherent nuclei such that the majority of “surviving” nuclei is coherent.

In the context of the herein described process, it should be acknowledged and is generally known in this field that a suitable “operating point” to carry out the PVD deposition process may vary from one PVD system to another. Therefore, knowing the present invention, the skilled person may have to adjust the suitable operating point and working parameters for a particular PVD system in respect of the deposition parameters. For the present invention, the reference PVD system is Hauzer HTC1000 (IHI Hauzer Techno Coating B.V., The Netherlands) with a chamber size of 1 m³.

In an embodiment of the process of the present invention the deposition of the tungsten carbide (WC) layer immediately on top of the substrate is carried out at a power density at the magnetron from 2 to 25 W/cm², preferably from 6 to 10 W/cm². In the examples herein below, 80 cm×20 cm (=1600 cm²) WC targets have been used, and the average total cathode power during deposition was 10 kW per target corresponding to 6.25 W/cm².

In another embodiment of the process of the present invention the deposition of the tungsten carbide (WC) layer immediately on top of the substrate is preferably carried out at a pulse length of from 5 to 5000 μs, more preferably of from 25 to 500 μs or from 50 to 100 μs.

In another embodiment of the process of the present invention, the deposition of the tungsten carbide (WC) layer immediately on top of the substrate is carried out at an average pulse current of from 250 to 1000 A.

In another embodiment of the process of the present invention, the deposition of the tungsten carbide (WC) layer immediately on top of the substrate is carried out at an average pulse power of from 100 kW to 2 MW.

In another embodiment of the process of the present invention, the deposition of the tungsten carbide (WC) layer immediately on top of the substrate is carried out at a temperature in the range from 200 to 600° C., preferably from 400 to 600° C. A too low temperature would require active cooling of the system. A too high temperature may impair the mechanical properties of the substrate and/or the coating. A very suitable deposition temperature in the examples herein below was about 550° C.

### DESCRIPTION OF THE FIGURES

FIG. 1 shows a SEM cross-section at 30.000× magnification of a cemented carbide substrate with a 93 nm thick inventive tungsten carbide (WC) layer deposited thereon (sample no. 190117005).

The line shows the interface between the substrate surface and the tungsten carbide (WC) layer. The circle marks a substrate WC grain with coherent growth of WC of the tungsten carbide layer thereon.

FIG. 2 shows a SEM cross-section at 30.000× magnification of a cemented carbide substrate with an inventive tungsten carbide (WC) layer deposited thereon (sample no. 190118001).

The line shows the interface between the substrate surface and the tungsten carbide (WC) layer and marks through the length of the line coherent growth transitions from substrate WC into the tungsten carbide layer.

FIG. 3 shows an XRD of the inventive tungsten carbide (WC) layer on cemented carbide substrate (sample no. 190117005), as shown in FIG. 1. The diffraction peaks are indexed according to JCPDS cards JCPDS 025-1047 (hexagonal α-WC) and JCPDS 020-1316 (cubic β-WC).

FIG. 4 shows an XRD of the inventive tungsten carbide (WC) layer on cemented carbide substrate (sample no. 190118001), as shown in FIG. 2. The diffraction peaks are indexed as in FIG. 3.

FIG. 5 shows a SEM cross section at 10.000× magnification of a cemented carbide substrate with a 30 nm thick inventive tungsten carbide (WC) layer (not visible at this magnification) and a multi-layer hard material coating deposited thereon. The coating sequence and the layer thicknesses are as follows:

| | | | |
|---|---|---|---|
| 1. | 30 | nm | inventive WC layer |
| 2. | 3.2 | μm | TiAlN layer |
| 3. | 179 | nm | Al₂O₃ layer |
| 4. | 280 | nm | 2 times alternating layers of TiAlN/Al₂O₃ |
| 5. | 245 | nm | TiAlN layer |
| 6. | 335 | nm | ZrN top layer |

The deposition parameters for the inventive WC layer (1) were the same as for sample no. 190118001 described below. The TiAlN layer (2) was deposited as described below in the cutting test example 2 for the layer stack L1+L2.

For the deposition of the Al₂O₃ layer (3), two Al-targets (80 cm×20 cm×10 mm each) were used and a dual magnetron was applied. The bias power supply was used in a bipolar pulsed mode with 45 kHz and an off-time of 10 ms. The magnetron power supply was pulsed with 60 kHz (±2 kHz), and the pulse form was sinus shape. The cathode voltage at the stabilized stage of the process was 390 V. The Vickers hardness of the Al₂O₃ layer was HV3100, and the Young's modulus was 380 GPa. The further deposition parameters for the Al₂O₃ layer were as follows:

| Parameter | Value |
|---|---|
| Ar flow [sccm] | 1220 |
| O₂ flow [sccm] | 101 |
| total pressure [mPa] | 1000 |
| O₂ part. press. [mPa] | 10.2 |
| Bias current [A] | 35.3 |
| Bias voltage [V] | −125 |
| Magnetron target | 20 |
| power [kW] | |
| Magnetron target | 6.2 |
| power density [W/cm²] | |
| Coil current [A] | 4.5 |

The TiAlN in the alternating layers of TiAlN/Al₂O₃ (4) and in layer (5) were deposited as described for layer L2 in the cutting test example 3. The Al₂O₃ in the alternating layers of TiAlN/Al₂O₃ (4) was deposited as described before fpr layer (3). The ZrN layer (6) was deposited by arc evaporation using an arc current of 150 A per target at 4 Pa nitrogen pressure using a bias voltage of −40 V.

FIG. 6 shows a SEM cross-section at 40.000× magnification of a detail of the sample shown in FIG. 5 at the transition from the cemented carbide substrate (left side) to the first TiAlN layer (right side) with the 30 nm inventive WC layer in between. FIG. 6 illustrates how the inventive tungsten carbide (WC) layer is suitable to cover Co veins exposed at the substrate surface between WC grains to provide a barrier against binder migration or diffusion, respectively, out of the substrate.

### EXAMPLES AND METHODS

### XRD (X-Ray Diffraction)

XRD measurements for phase analysis were done applying grazing incidence mode (GIXRD) on a diffractometer from Panalytical (Empyrean) using CuKα-radiation. The X-ray tube was run with line focus at 40 kV and 40 mA. The incident beam was defined by a 2 mm mask and a ⅛° divergence slit in addition to an X-ray mirror producing a parallel X-ray beam. The sideways divergence was controlled by a Soller slit with a divergence of 0.04°. For the diffracted beam path a 0.18° parallel plate collimator in conjunction with a proportional counter (OD-detector) was used. The measurement was done in grazing incidence mode (Omega=1°). The 2-theta range was about 20-80° with a step size of 0.03° and a counting time of 10 s. For the XRD-line-profile analysis a reference measurement with LaB6-powder was done under the same parameters as described above to correct for the instrumental broadening.

### Hardness/Young's Modulus Measurement

The measurements of hardness and Young's modulus (=reduced Young's modulus) were performed on the flank face of the coated tools by the nanoindentation method on a Fischerscope® HM500 Picodentor (Helmut Fischer GmbH, Sindelfingen, DE) applying the Oliver and Pharr evaluation algorithm, wherein a diamond test body according to Vickers was pressed into the layer and the force-path curve was recorded during the measurement (maximum load: 15 mN; load/unload time: 20 s; creep time: 5 s). From this curve hardness and (reduced) Young's modulus were calculated.

### Scanning Electron Microscopy (SEM)

The morphology of the coatings was studied by scanning electron microscopy (SEM) using a Supra 40 VP (Carl Zeiss Microscopy GmbH, Jena, Germany). Cross sections were characterized with the SE2 (Everhart-Thornley) Detector.

### Substrates for Cutting Tests

For the preparation of cutting tools used in cutting tests cemented carbide cutting tool substrate bodies of the following specification were used:

Composition: 12 wt-% Co, 1.6 wt-% (Ta, Nb)C, balance WC
WC grain size: ˜1.5 μm

### Geometry: ADMT160608R-F56

Vickers hardness: ˜1600 HV (unpolished surface); ˜2000 HV (polished surface)

### Substrates for Analytics

For analytics of the deposited tungsten carbide layer of the present invention cemented carbide substrates of simple flat square geometry with side lengths of 15 mm with a polished surface and of the following specification were used:

Composition: 8 wt-% Co, balance WC
WC grain size: ˜1.5 μm
Vickers hardness: ˜2000 HV (on the polished surface)

### PVD Coating

Prior to the deposition, the substrate bodies were pretreated by ultrasonic cleaning in ethanol and plasma cleaning. The PVD reactor was evacuated to 8×10⁻⁵ mbar, and the substrate bodies were pre-treated at 550° C.

The tungsten carbide (WC) coatings were produced by the High-Power Impulse Magnetron Sputtering (HIPIMS) process in a 6-flange PVD installation Hauzer HTC1000 (IHI Hauzer Techno Coating B.V., NL) with a chamber size of 1 m³. The substrates were rotated on rotary tables. For the HIPIMS process, a plasma generator by TRUMPF Hüttinger GmbH+Co. KG, Freiburg, DE, was used. In the PVD system one WC target of 80 cm×20 cm was used for the deposition of the tungsten carbide (WC) layer on top of the substrate surface. The depositions were run in an Ar atmosphere with the addition of C₂H₂. The total pressure during deposition was 0.7 Pa (7.0×10⁻³ mbar) corresponding to an Ar flow of ˜900 sccm. The deposition temperature was 550° C.

The C₂H₂ flows/partial pressures during the depositions were either zero or
10 sccm C₂H₂/˜0.008 Pa (8.0×10⁻⁵ mbar) C₂H₂
15 sccm C₂H₂/˜0.013 Pa (1.3×10⁻⁴ mbar) C₂H₂
30 sccm C₂H₂/˜0.02 Pa (2.0×10⁻⁴ mbar) C₂H₂

The HIPIMS average total cathode power during deposition was 10 kW corresponding to about 6.25 W/cm² of the target. The remaining deposition parameters, “bias voltage”, “average pulse power”, “peak voltage”, “peak current”, “pulse length” and “frequency” were varied and are indicated in table 1 below. The values given are average values since the plasma conditions change constantly as the substrate table is moved.

### Example 1—HIPIMS Depositions of Coatings According to the Invention and Comparative Coatings

The parameters of the HIPIMS deposition of the tungsten carbide (WC) layer are indicated in table 1, and the results are given in table 2. The HIPIMS depositions were carried out to obtain tungsten carbide (WC) layer thicknesses of about 90 to 100 μm measured on SEM cross-sections. The substrates in this example were the above-described substrates for analytics.

TABLE 1
HIPIMS deposition parameters for WC coating layer

| | Average Pulse | Peak Voltage/ | Pulse Length/ | C₂H₂ Flow/ | Bias |
|---|---|---|---|---|---|
| | Power | Peak Current | Frequency | Ar flow | Voltage |
| Sample # | [MW] | [V]/[A] | [μs]/[Hz] | [sccm/sccm] | [V] |
| 181015002 | 0.45 | 1600 V/700 A | 50 μs/450 Hz | —/900 | 100 V |
| 181017002 | 0.63 | 1600 V/700 A | 100 μs/160 Hz | —/900 | 100 V |
| 181023003 | 0.32 | 1200 V/550 A | 100 μs/308 Hz | 30/900 | 40 V |
| 181023004 | 0.32 | 1200 V/550 A | 100 μs/308 Hz | 30/900 | 100 V |
| 181025002 | 0.15 | 1000 V/230 A | 500 μs/130 Hz | 10/900 | 150 V |
| 181025003 | 0.54 | 1700 V/845 A | 50 μs/370 Hz | 10/900 | 100 V |
| 181026001 | 0.54 | 1700 V/845 A | 50 μs/370 Hz | 10/900 | 150 V |
| 181026003 | 0.54 | 1700 V/845 A | 50 μs/370 Hz | 15/900 | 100 V |
| 190117005 | 0.45 | 1600 V/800 A | 50 μs/446 Hz | 15/900 | 200 V |
| 190118001 | 0.22 | 1200 V/270 A | 500 μs/91 Hz | 15/900 | 200 V |

TABLE 2
Results

| | | Young's | | Evaluation |
|---|---|---|---|---|
| | Hardness | Modulus | WC Phases | Mechanical |
| Sample # | [HV] | [GPa] | in XRD | Properties |
| 181015002 | 2720 | 515 | α-WC (+)/β-WC (+)/α-W₂C (+) | −−− |
| 181017002 | 2900 | 525 | α-WC (+)/β-WC (+)/α-W₂C (+) | −−− |
| 181023003 | 2200 | 410 | α-WC (+)/β-WC (+)/α-W₂C (−) | −− |
| 181023004 | 2215 | 440 | α-WC (+)/β-WC (+)/α-W₂C (−) | −− |
| 181025002 | 2720 | 515 | α-WC (+)/β-WC (+)/α-W₂C (+) | −−− |
| 181025003 | 2780 | 520 | α-WC (+)/β-WC (+)/α-W₂C (+) | −−− |
| 181026001 | 3020 | 545 | α-WC (+)/β-WC (+)/α-W₂C (+) | −−− |
| 181026003 | 2750 | 510 | α-WC (+)/β-WC (+)/α-W₂C (+) | −−− |
| 190117005 | 2700 | 500 | α-WC (+)/β-WC (+)/α-W₂C (−) | +++ |
| 190118001 | 2835 | 550 | α-WC (+)/β-WC (+)/α-W₂C (−) | +++ |

“(+)” and “(−)”indicates whether or not the respective tungsten carbide phase could be detected by XRD indexed applying JCPDS cards 025-1047, 020-1313 and 035-0776, as described above.
α-WC (+/−): hexagonal tungsten mono-carbide α-WC detected/not detected
β-WC (+/−): cubic tungsten mono-carbide β-WC detected/not detected
α-W₂C (+/−): hexagonal tungsten semi-carbide α-W₂C detected/not detected

In samples 181015002, 181017002, 181025002, 181025003, 181026001 and 181026003, where no or only 10 sccm C₂H₂ was introduced, the undesired brittle semi-carbide α-W₂C was detected in XRD. Even though, hardness and Young's modulus of these samples were quite high, the mechanical properties of these samples were insufficient. The tungsten carbide layer was brittle, probably due to the presence of significant amounts of α-W₂C, and adherence to the substrate was bad.

In samples 181023003 and 181023004 no semi-carbide α-W₂C was detected in XRD, however, the samples exhibited low hardness and low Young's modulus, i.e. insufficient mechanical properties. The high (over-stoichiometric) C₂H₂ flow of 30 sccm resulted in the incorporation of graphite or amorphous carbon, respectively, into the deposited layer, which in turn led to the insufficient mechanical properties.

Samples 190117005 and 190118001 showed no semi-carbide α-W₂C in XRD, and the samples exhibited high hardness, high Young's modulus, good overall mechanical properties and good adhesion to the cemented carbide substrate. These outstanding properties resulted from an optimized combination of the C₂H₂ flow and the applied high bias in the HIPIMS deposition process. Therefore, the tungsten carbide layers of these samples are suitable as wear resistant outer layers, but also as an intermediate layers for subsequent hard material coating layers of a cutting tool.

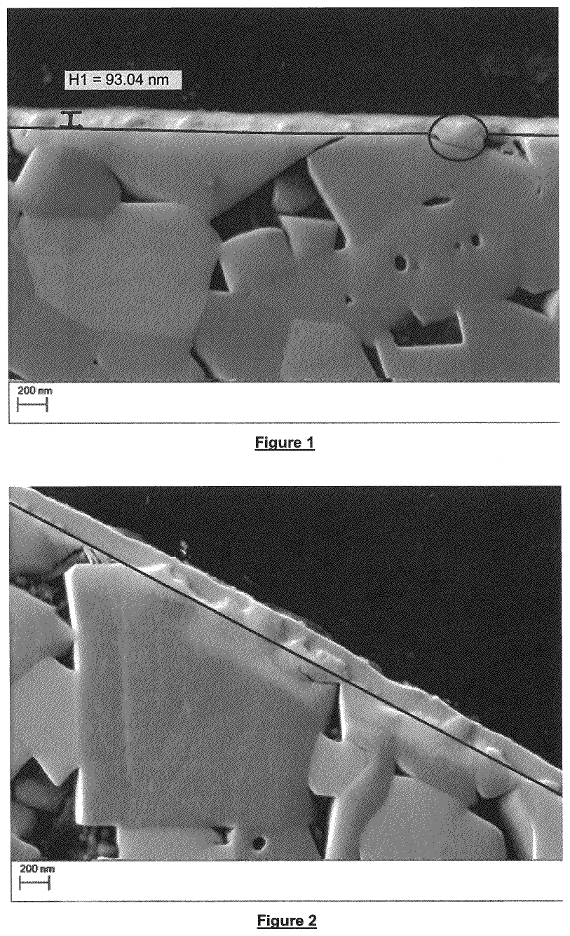

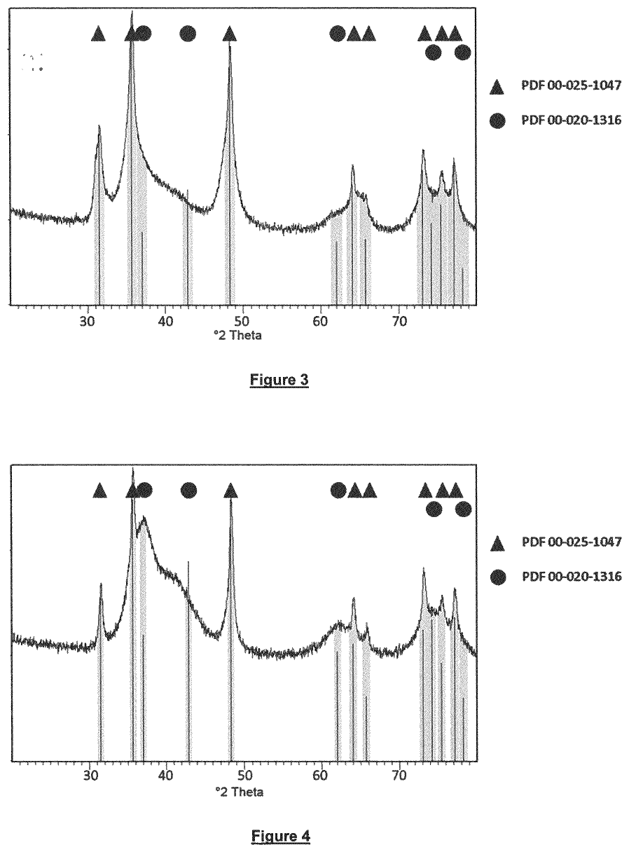

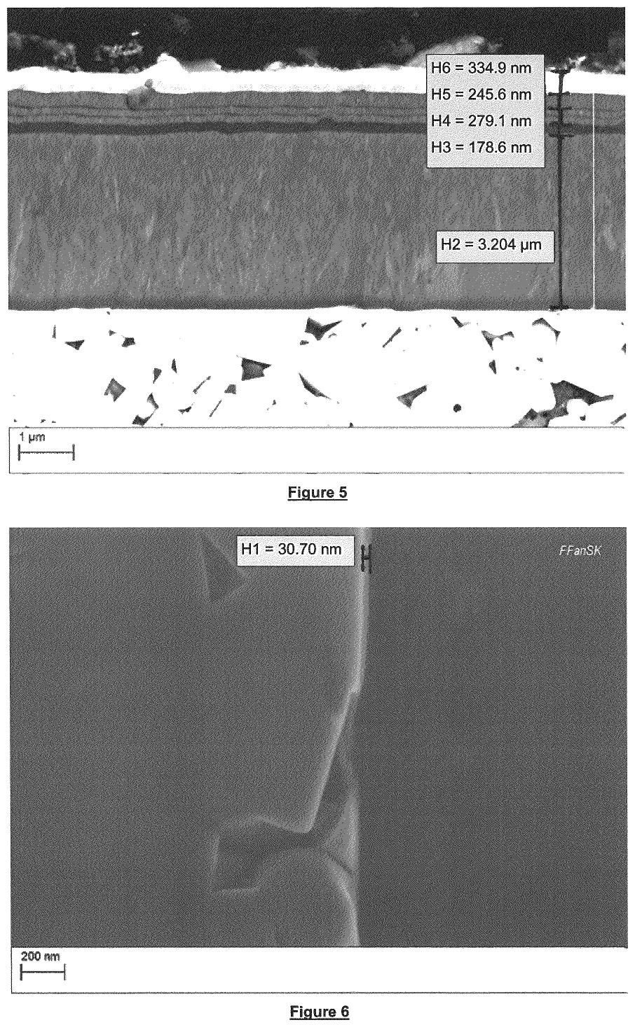

As can well be seen in the SEM cross-sections in FIGS. 1 and 2, samples 190117005 and 190118001 showed a high degree of coherent growth of the tungsten carbide layers on the substrate WC grain surfaces.

In the examples shown herein the deposition parameters and conditions for a sample were kept constant throughout the deposition of the entire tungsten carbide (WC) layer thickness. However, by variation of the deposition parameters during growth of the tungsten carbide (WC) layer it was possible to change the phase distribution (amounts or ratios of tungsten mono-carbide α-WC and tungsten mono-carbide β-WC phases) and, at the same time, avoid the formation of undesired hexagonal α-W₂C semi-carbide phase, as could be confirmed by TEM analysis.

For example, changing the phase distribution (amounts or ratios) from a higher to a lower ratio of hexagonal α-WC/cubic β-WC phase from the substrate surface towards the outer surface of the deposited tungsten carbide (WC) layer, was achieved by slightly lowering the C₂H₂ flow (partial pressure) within the optimized working window of the deposition process.

It has been found and confirmed by the examples that in the HIPIMS process of the present invention the combination of a comparably high bias voltage and of a suitably high C₂H₂ flow (partial pressure) is beneficial to obtain hexagonal tungsten mono-carbide α-WC and cubic tungsten monocarbide β-WC phases without detectable amounts of detrimental and thus undesired hexagonal semi-carbide α-W₂C, and results in an improvement of the coherent transition from the WC grains of the substrate surface into the tungsten carbide (WC) coating layer. No C₂H₂ or a too low amount of C₂H₂ always results in the deposition of significant amounts of the undesired hexagonal semi-carbide α-W₂C. A too high amount of C₂H₂ gives additional C phases (graphite or amorphous C, respectively). And a too low bias does not result in coherent transition from the WC grains of the substrate surface into the tungsten carbide (WC) coating layer.

### Example 2—Cutting Tests

In order to assess the effect of the inventive tungsten carbide (WC) layer according to the invention coated cutting tools were produced and tested in a milling test.

For the cutting tests in this example cemented carbide substrates of the type described above for cutting tests were used. Inventive examples were coated with an about 30 nm thick tungsten carbide (WC) layer deposited immediately on top of the substrate surface as described above in example 1 for sample no. 190117005.

Subsequently, the substrates with the WC layer (invention) and without the WC layer (comparative example) were coated in the arc evaporation process with a TiAlN coating consisting of a first 2.0 μm thick layer L1 and a second 2.0 μm thick layer L2, i.e. a total thickness of 4 μm. The deposition conditions for L1 and L2 were as follows:

| (Ti,Al)N | Targets | “Ti50Al50” + “Ti33Al67” | |
|---|---|---|---|
| sub-layer L1 | Bias | −40 | V |
| | Pressure (N₂) | 10 | Pa |
| | Arc Current/Target | 150 | A |
| | Rotation Speed | 3 | rpm |
| | Temperature | 550° | C. |
| (Ti,Al)N | Targets | “Ti33Al67” + “Ti50Al50” + “Ti33Al67” | |
| sub-layer L2 | Bias | −40 | V |
| | Pressure | 10 | Pa |
| | Arc Current/Target | 150 | A |
| | Rotation Speed | 3 | rpm |
| | Temperature | 550° | C. |

The cutting tests were performed on a Fritz Werner TC630 machine under the following conditions, and the maximum wear V_{Bmax}, i.e. the deepest crater observed on the flank face of the tool, was determined after the test.

### Cutting Conditions:

Tooth Feed f_{z} [mm/tooth]: 0.2
Feed v_{f} [mm/min]: 120
Cutting speed v_{c} [m/min]: 188
Cutting depth aₚ [mm]: 3
Workpiece material: 42CrMo4 (tensile strength Rm: 850 N/mm²)
Cutting length [mm]: 5600

V_{Bmax} of the inventive tool provided with the inventive tungsten carbide (WC) layer was 0.14 mm, whereas V_{Bmax} of the comparative tool was 0.16 mm, i.e. the wear of the comparative tool was about 14% higher than of the inventive tool.

In addition, a cutting tool provided with a tungsten carbide layer containing a certain measurable amount of semi-carbide α-W₂C was produced, as described above in example 1, and tested in the cutting test. However, no meaningful result could be obtained, since the tool quickly failed after starting the test due to brittleness of the tungsten carbide layer.

The results clearly show the advantages of a cutting tools according to the invention.

1. A coated cutting tool comprising:
substrate of cemented carbide, cermet containing tungsten carbide hard grains or cubic boron nitride; and
tungsten carbide layer deposited immediately on top of the substrate surface, wherein the tungsten carbide layer consists of a mixture or combination of hexagonal tungsten mono-carbide α-WC phase and cubic tungsten mono-carbide β-WC phase and unavoidable impurities.

2. The coated cutting tool of claim 1, wherein the tungsten carbide layer has a thickness of from 1 nm to 5 μm.

3. The coated cutting tool of claim 1, wherein a single-layer or multi-layer hard material coating is deposited immediately on top of the tungsten carbide layer, wherein the hard material coating includes at least one layer of hard material selected from the group consisting of nitrides, carbides, oxides, borides and/or solid solutions thereof of one or more of the elements selected from Ti, Zr, Hf, V, Nb, Ta, Cr, Mo, W, Al and Si.

4. The coated cutting tool of claim 1, wherein the substrate is a cemented carbide consisting of from 3 to 30 wt % of a binder phase of Co, Fe and/or Ni, 0 to 20 wt-% of cubic carbides, nitrides and/or carbonitrides of group IV, V and/or VI transition metals and rest tungsten carbide hard material grains.

5. The coated cutting tool of claim 1, wherein the tungsten carbide layer is deposited by a PVD method selected from HIPIMS and DMS.

6. The coated cutting tool of claim 1, wherein an amount of hexagonal tungsten mono-carbide α-WC phase within the tungsten carbide layer decreases and an amount of cubic tungsten mono-carbide β-WC phase increases from an interface at a surface of the substrate towards an outer surface of the tungsten carbide (WC) layer, whereby a change of phase amounts is gradual or stepwise.

7. The coated cutting tool of claim 1, wherein the tungsten carbide layer has a Vickers hardness HV0.015≥2500 and/or a reduced Young's modulus>450 GPa.

8. The coated cutting tool of claim 1, wherein there is a coherent transition from tungsten carbide grains exposed at a substrate surface to the tungsten carbide layer deposited immediately on top of the substrate surface, as observed by SEM.

9. A process for manufacturing a coated cutting tool according to claim 1, wherein the tungsten carbide layer immediately on top of the substrate is deposited by HIPIMS or DMS using a reaction gas composition comprising or consisting of argon and a carbon source gas, wherein the carbon source gas is provided at a partial pressure within the range from at least 4×10⁻⁵ mbar to at most 2.0×10⁻⁴ mbar, and wherein the bias voltage is within the range from 80 to 250 V.

10. The process according to claim 9, wherein the deposition of the tungsten carbide layer immediately on top of the substrate is carried out at a power density at the magnetron is from 2 to 25 W/cm².

11. The process according to claim 9, wherein the deposition of the tungsten carbide layer immediately on top of the substrate is carried out at a pulse length of from 5 to 5000 μs.

12. The process according to claim 9, wherein the deposition of the tungsten carbide layer immediately on top of the substrate is carried out at an average pulse current of from 250 to 1000 A.

13. The process according to claim 9, wherein the deposition of the tungsten carbide layer immediately on top of the substrate is carried out at an average pulse power of from 100 kW to 2 MW.

14. The process according to claim 9, wherein the deposition of the tungsten carbide layer immediately on top of the substrate is carried out at a temperature in the range from 200 to 600° C.

15. The coated cutting tool of claim 3, wherein hard material coating includes two or more layers of hard material.

16. The coated cutting tool of claim 3, wherein the hard material is selected from the group consisting of TiN, TiC, TiAlN, TiAlC, TiAlCN, a Al₂O₃, γ Al₂O₃.

17. The coated cutting tool of claim 4, wherein the binder phase is Co.

18. The process according to claim 9, wherein the carbon source gas is C₂H₂.
